(19) United States
(12) Patent Application Publication
(10) Pub. No.: US 2012/0268658 A1
(43) Pub. Date: Oct. 25, 2012

(54) TELEVISION AND ELECTRONIC APPARATUS

(75) Inventor: Kenji HASEGAWA, Hamura-shi (JP)

(73) Assignee: KABUSHIKI KAISHA TOSHIBA, Tokyo (JP)

(21) Appl. No.: 13/346,561

(22) Filed: Jan. 9, 2012

(30) Foreign Application Priority Data
Apr. 20, 2011 (JP) 2011-094281

(51) Int. Cl. H04N 5/50; H05K 7/00; H04N 5/64

(52) U.S. Cl. 348/731; 361/679.01; 348/E05.128; 348/E05.097

(57) ABSTRACT

According to one embodiment, an electronic apparatus includes a housing and a module. The housing includes an opening portion. The module includes a first region colored in a first color and a second region exposed from the opening portion and colored in a second color which is different from the first color.

### CROSS-REFERENCE TO RELATED APPLICATIONS

This application is based upon and claims the benefit of priority from prior Japanese Patent Application No. 2011-094281, filed Apr. 20, 2011, the entire contents of which are incorporated herein by reference.

### FIELD

Embodiments described herein relate generally to a television and an electronic apparatus.

### BACKGROUND

An electronic apparatus such as a television or a portable computer comprises a printed wiring board on which electronic parts are mounted. A substrate such as a printed wiring board comprises a colored solder resist layer which protects, for example, a conductive layer from solder. The color of the solder resist may be determined from the viewpoint of designing.

An electronic apparatus in which parts built therein are colored from the viewpoint of making a better design is still susceptible to improvement.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view showing a television of the first embodiment;

FIG. 2 is an exemplary perspective rear and partially cut-away view of the television of the first embodiment;

FIG. 3 is an exemplary plan view showing a printed circuit board of the first embodiment;

FIG. 4 is an exemplary cross sectional view of a part of the printed circuit board of the first embodiment, taken along the line F4-F4 of FIG. 3;

FIG. 5 is an exemplary cross sectional view of a part of the printed circuit board of the first embodiment, taken along the line F5-F5 of FIG. 3;

FIG. 6 is an exemplary plan view showing a printed circuit board of the second embodiment;

FIG. 7 is an exemplary cross sectional view of a part of the television of the second embodiment, taken along the line F7-F7 of FIG. 6;

FIG. 8 is an exemplary perspective view schematically showing a copper clad laminate and a coating device in the second embodiment;

FIG. 9 is an exemplary perspective and partially cut-away view of a portable computer of the third embodiment;

FIG. 10 is an exemplary plan and partially cut-away view showing a bottom surface of the portable computer of the third embodiment; and

FIG. 11 is an exemplary cross sectional view of a part of the portable computer of the third embodiment, taken along the line F11-F11 of FIG. 9.

### DETAILED DESCRIPTION

Various embodiments will be described hereinafter with reference to the accompanying drawings.

In general, according to one embodiment, an electronic apparatus includes a housing and a module. The housing includes an opening portion. The module includes a first region colored in a first color and a second region exposed from the opening portion and colored in a second color which is different from the first color.

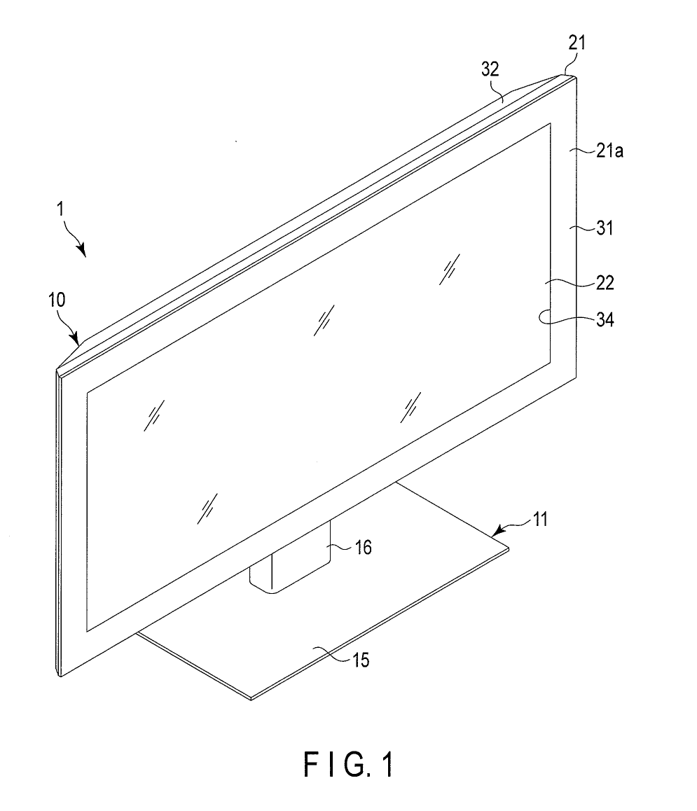

The first embodiment will now be described with reference to FIGS. 1 to 5. FIG. 1 is an exemplary perspective view showing a television 1 of the first embodiment, an.

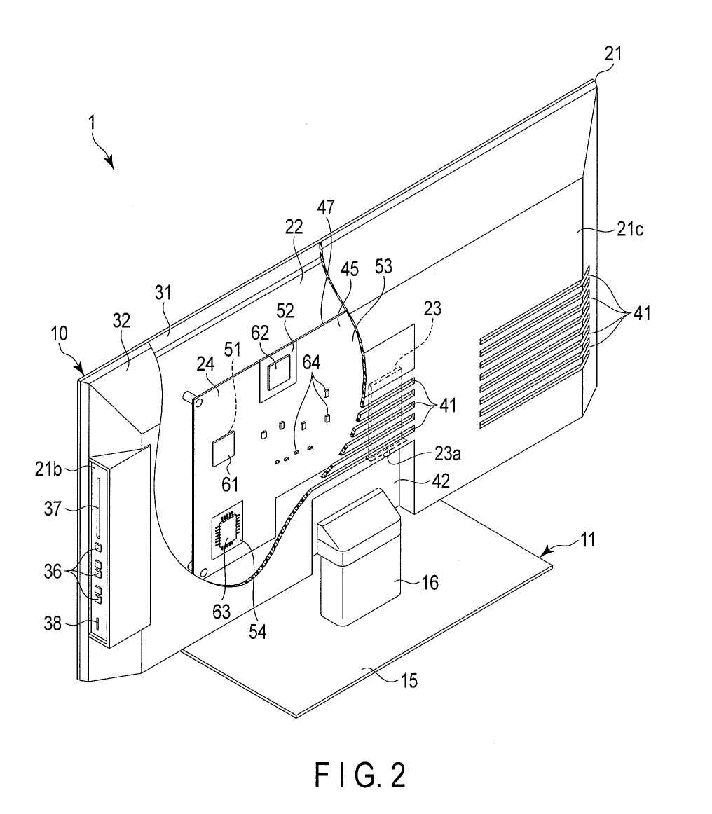

FIG. 2 is an exemplary perspective view showing the television 1 partially cut away and from the back (opposite side to FIG. 1). The television is an example of the electronic apparatus.

As shown in FIG. 1, the television 1 comprises a display device 10 and a stand 11. The stand 11 comprises a base portion (support portion, support, first support portion, first support) 15, and a support pole (support portion, support, connection portion, projection portion, second support portion, second support) 16. The base portion 15 is formed into a rectangular plate. A bottom surface of the base portion 15 (the surface opposite to the display device 10, wall portion, wall, surface, portion, region) is provided with, for example, a plurality of rubber legs (support portion, support, third support potion, third support). The support pole 16 projects from the base portion 15. The support pole 16 supports the display device 10 as it is connected to the display device 10.

As shown in FIG. 2, the display device 10 comprises a housing 21, a display module 22, a tuner 23 and a printed wiring board 24. The printed wiring board 24 is an example of the substrate and module. In this specification, the printed wiring board includes members called substrate, circuit board and printed circuit board. Each of the display module 22, tuner 23 and printed wiring board 24 is housed in the housing 21.

The housing 21 comprises a front cover (first cover, cover portion, housing, portion, region) 31 and a rear cover (second cover, cover portion, housing, portion, region) 32. The front cover 31 forms a front surface portion (portion which forms the surface on the user side viewing the screen image, wall portion, wall, surface, portion, region) 21a of the housing 21 shown in FIG. 1. The rear cover 32 forms side surface portions 21b and a rear surface portion (portion which forms the surface on an opposite side to the front surface portion 21a, wall portion, wall, surface, portion, region) 21c of the housing 21. It should be noted here that the side surface portions of the housing 21 (portions extending between the front and rear surfaces, wall portion, wall, surface, portion, region) 21b of the housing 21 may be made of the front cover 31.

As shown in FIG. 1, a display opening (opening portion) 34 is provided in the front surface portion 21a of the housing 21. The display opening 34 exposes the display module 22. It should be noted that the display module 22 may be exposed directly from the display opening 34, or the display module 22 may be exposed via, for example, a translucent filter which covers the front surface portion 21a of the housing 21.

The display module 22 is, for example, a liquid crystal display, and is formed into a rectangular plate. It should be noted that the display module 22 may be some other type of display such as a plasma display or an organic EL display. The display module 22 displays images such as motion images or still images on the display surface exposed from the display opening 34.

As shown in FIG. 2, a plurality of buttons 36, a card insertion opening (opening portion) 37, and a medium insertion opening (opening portion) 38 are formed on and in the side surface portions 21b of the housing 21. The plurality of buttons 36 are used as, for example, a power switch, a channel adjustment and a volume adjustment, respectively. The card insertion opening 37 is an opening (opening portion) into which, for example, a B-CAS card is inserted. The medium insertion opening 38 is an opening (opening portion) into which, for example, a memory card is inserted.

A plurality of ventilation openings (opening portions) 41 and a recess portion (opening portion) 42 are formed in the rear surface portion 21c of the housing 21. The ventilation openings 41 are an example of the opening portion. The ventilation openings 41 are used as air inlets or air exhaust outlets for cooling the inside of the housing 21. It should be noted that the ventilation openings 41 may be formed in, for example, the side surface portions 21b in place of the rear surface portion 21c of the housing 21.

The recess portion 42 is formed to recess from the rear surface portion 21c of the housing 21. The support pole 16 is fixed to the recess portion 42 by, for example, a screw. A plurality of connectors such as a USB connector and HDMI connector are provided in the recess portion 42.

The tuner 23 is electrically connected to the printed wiring board 24. The tuner 23 comprises a terminal 23a protruding from the recess portion 42. A feeder is connected to the terminal 23a of the tuner 23. It should be noted that the display device 10 may further comprise a plurality of other tuners. In this case, the terminal 23a is shared by the tuner 23 and the plurality of other tuners.

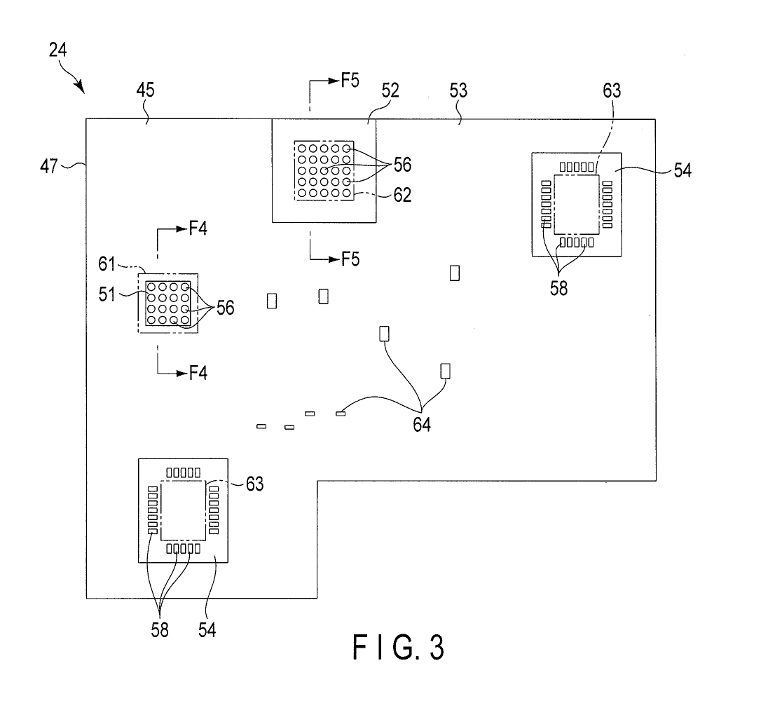

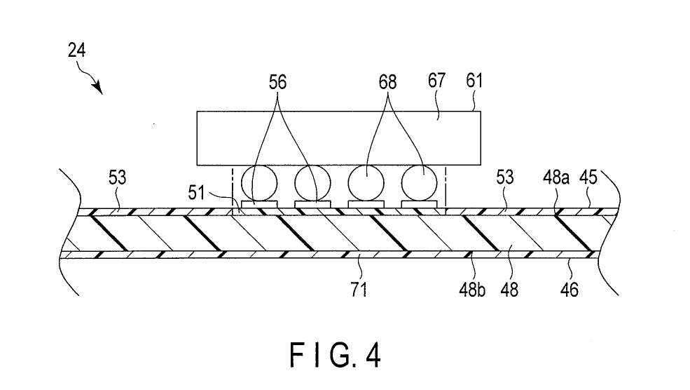

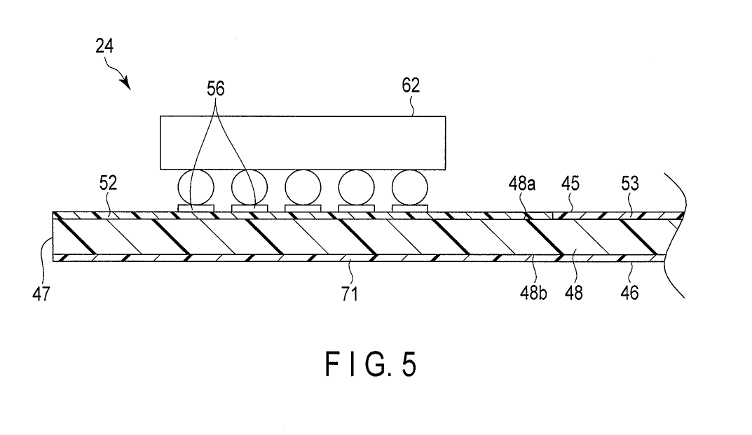

FIG. 3 is an exemplary plan view showing the printed circuit board 24. FIG. 4 is an exemplary cross sectional view of a part of the printed circuit board 24, taken along the line F4-F4 of FIG. 3. FIG. 5 is an exemplary cross sectional view of a part of the printed circuit board 24, taken along the line F5-F5 of FIG. 3.

As shown in FIG. 5, the printed circuit board 24 comprises a first surface 45, a second surface 46 and a edge portion 47. The first surface 45 is an example of the component mount side. The printed circuit board 24 of the first embodiment is a printed circuit board of the so-called single sided mounting mode.

As shown in FIG. 2, the first surface 45 faces an inner surface of the rear cover 32. The second surface 46 is located on an opposite side to the first surface 45, and it faces the display module 22. The edge portion 47 is formed from the first surface 45 over to the second surface 46.

The printed wiring board 24 comprises, for example, a plurality of insulation plates, a plurality of conducting layers and a plurality of solder resists (coating, material), all stacking one on another. It should be noted that in FIGS. 4 and 5, the plurality of insulation plates and the plurality of conducting layers stacking one on another are shown as an integrated member as a copper clad laminate (conducting portion, conducting substrate, substrate, plate, conductive layer, layer, base portion) 48. The copper clad laminate 48 is a portion of the printed wiring board 24 excluding the solder resist.

As shown in FIG. 3, two first regions 51 and 52, a second region 53 and two of third regions 54 are formed in the first surface 45. As shown in FIG. 4, the first to third regions 51, 52, 53 and 54 are each formed of the solder resist applied on one surface 48a of the copper clad laminate 48. The first to third regions 51, 52, 53 and 54 are formed continuously to be substantially flat.

The first regions 51 and 52 are formed of a solder resist colored in blue. Blue is an example of the first color. The color of the first regions 51 and 52 is not limited to this, but they may alternatively be formed of a solder resist colored in, for example, green.

As shown in FIG. 3, the first regions 51 and 52 are each formed into substantially a square shape. The shape of the first regions 51 and 52 is not limited to this, but they may alternatively be formed into some other shape, for example, rectangular or circular. The first region 51 is formed to be narrower than the other first region 52. The first region 52 is placed adjacent to the edge portion 47 of the printed wiring board 24.

The first regions 51 and 52 each comprise a plurality of pads 56. The plurality of pads 56 are an example of the conducting portion. The plurality of pads 56 are arranged in matrix in each of the first regions 51 and 52.

The second region 53 is formed of a solder resist colored in glossy black. Black is an example of the second color which is different from the first color. Note that the color of the second region 53 is not limited to perfect black, but this black color, as long as it is darker than the blue of the first regions 51 and 52, may be tinged with, for example, blue. On the other hand, the color of the first regions 51 and 52 may be deep blue tinged with, for example, black as long as it is more blackish than the blue color of the first regions 51 and 52.

The solder resist colored in the second color has different properties from those of the solder resist colored in the first color. That is, for example, due to the difference in light absorbing amount, the solder resist of the blue color, which is an example of the first color, has a resolution higher than that of the solder resist of the black color, which is an example of the second color. The resolution represents how narrow the line of a pattern can be when forming the pattern. That is, a finer pattern or dot can be formed in the first regions 51 and 52 colored in the first color than in the second region 53 colored in the second color.

The second region 53 is formed to surround the first regions 51 and 52. In other words, the second region 53 is set adjacent to the first regions 51 and 52. As shown in FIG. 2, a part of the second region 53 is placed in the vicinity of the plurality of ventilation openings 41. In other words, the part of the second region 53 is placed at a position visible from the plurality of ventilation openings 41. The second region 53 is colored in black, which is a dark cooler, and therefore it is not conspicuous when viewed through the ventilation openings 41.

The two of the third regions 54 are formed of a solder resist colored in green. Green is an example of the third color which is different from the first color or the second color. The color of the third regions 54 is not limited to this, but they may alternatively be formed of a solder resist colored in, for example, blue.

As shown in FIG. 3, the third regions 54 each comprise a plurality of pads 58. The plurality of pads 58 are arranged to line in a frame-like manner in each of the two of the third regions 54.

On the first surface 45, mounted are two BGAs 61 and 62, two QFPs 63 and a plurality of other electronic parts 64 such as capacitors. The BGAs 61 and 62 are an example of the electronic part. The BGAs 61 and 62 and QFPs 63 are the so-called high density (fine line) mounting parts. In FIG. 3, the BGAs 61 and 62 and QFPs 63 are each indicated by alternate long and two short dashes lines. FIGS. 4 and 5 each show side surfaces of the BGAs 61 and 62.

As shown in FIG. 4, one BGA 61 comprises a package portion 67 and a plurality of terminals 68. The package portion 67 is formed into substantially a square plate, and colored in delustered black. The package portion 67 is formed larger than the one first region 51 so as to cover this first region 51.

The plurality of terminals 68 are solder balls each projecting from the bottom surface (surface facing the first surface 45) of the package portion 67. The plurality of terminals 68 are electrically connected respectively to the plurality of pads 56 formed in the first region 51.

As shown in FIG. 5, the other BGA 62 is electrically connected to the plurality of pads 56 formed in the other first region 52. The first region 52 is formed larger than the BGA 62.

As shown in FIG. 3, the two QFP 63 are electrically connected to the plurality of pads 58 formed in the two of the third regions 54, respectively. The plurality of the other electronic parts 64 are each mounted in the second region 53.

The first to third regions 51, 52, 53 and 54 are formed, for example, in the following manner. First, a solder resist colored in black is applied on one surface 48a of the copper clad laminate 48 by screen printing. Next, a masking film is placed on the black solder resist (on an opposite side to the copper clad laminate 48). Next, by performing exposure, the black solder resist at the portion where the second region 53 is provided is hardened, and the resultant is subjected to etching. In this manner, the second region 53 is formed. Next, a solder resist colored in blue is applied to the portion of the copper clad laminate 48 where the second region 53 is not formed. Then, masking, exposure and etching are carried out to form the first regions 51 and 52. Next, a solder resist colored in green is applied to the portion of the copper clad laminate 48 where the first and second regions 51, 52 and 53 are not formed. Then, masking, exposure and etching are carried out to form the third region 54. In this manner, the first to third regions 51, 52, 53 and 54 are formed.

As shown in FIG. 5, the second surface 46 of the printed wiring board 24 is formed of a solder resist layer 71. The solder resist layer 71 is formed of a solder resist applied on the other surface 48b of the copper clad laminate 48. The solder resist layer 71 is colored in, for example, black. The color of the solder resist layer 71 is not limited to black, but it may be some other color such as blue.

The edge portion 47 of the printed wiring board 24 is colored in glossy black similar to that of the second region. The edge portion 47 is painted with, for example, ink. It should be note that the edge portion 47 may be formed of a solder resist.

According to the television 1 having the above-described structure, the second region 53, a part of which is located at a position visible from the ventilation openings 41, is colored in black. With this structure, the printed wiring board 24 is made inconspicuous, and thus the design of the television 1 is improved.

On the other hand, the first regions 51 and 52 are colored in blue which has a resolution higher than that of black. In the first regions 51 and 52, the plurality of pads 56 are formed respectively, to which the so-called high density (fine line) mounting parts, BGAs 61 and 62 are electrically connected. Since blue has a resolution higher than that of black, the pads 56 can be formed finely to match the BGAs 61 and 62.

Further, the printed wiring board 24 is subjected to the optical automatic inspection in its manufacturing process. More specifically, using such an instrument as camera or sensor, the status of the formation of patterns or the status of the mounting of parts is inspected. Blue or green as an example of the first color can be more easily identified in the optical automatic specification than black as an example of the second color. For example, with some camera or sensor, there are some cases where it is difficult to discriminate the black color of the second region 53 and the black color of the package portion 67 of the BGAs 61 and 62 from each other. Here, the first regions 51 and 52 in which the BGAs 61 and 62 are mounted are colored in blue, and thus the optical automatic inspection can be easily performed.

As described above, the color of the first regions 51 and 52 and the color of the second region 53 can be determined in accordance with the conditions of the first regions 51 and 52 and the second region 53, respectively. In this manner, even if the section visible from the ventilation openings 41 is colored in black, the high density (fine line) mounting parts, namely, the BGAs 61 and 62, can be easily mounted on the printed wiring board 24. Thus, the design of the television 1 can be improved by suppressing the demerits.

The first regions 51 and 52 colored in blue and the second region 53 colored in black are formed in the first surface 45 of the printed wiring board 24. With this structure, even if the first surface 45 on which electronic parts such as the BGA 61 are mounted is visible from opening portions such as the ventilation openings 41, the section visible from the ventilation openings 41 can be colored in black which is inconspicuous. Thus, the design of the television 1 can be improved.

One first region 51 is covered by the package portion 67 of one BGA 61. In other words, the first region 51 colored in blue is covered under the package portion 67. In this manner, the design of the television 1 can be improved.

The third region 54 is colored in green. With this structure, the first regions 51 and 52 where the BGAs 61 and 62 are mounted and the third region 54 in which the QFP 63 is mounted can be easily discriminated from each other. Thus, the manufacturing process of the television 1 can be facilitated.

The edge portion 47 of the printed wiring board 24 is colored in the same black color as that of the second region 53. With this structure, even if the edge portion 47 is viewed through openings such as the ventilation openings 41, the printed wiring board 24 is inconspicuous. Therefore, the design of the television 1 can be improved.

It should be noted here that the method of forming the first to third regions 51, 52, 53 and 54 is not limited to that described above. It is alternatively possible to form the second region 53 in the entire region of the one surface 48a of the copper clad laminate 48 and form the first regions 51 and 52 and the third region 54 on the second region 53 (on an opposite side to the copper clad laminate 48).

Further, the first regions 51 and 52, the second region 53 and the third region 54 are not limited to the type formed of a colored solder resist. For example, the first to third regions 51, 52, 53 and 54 may be portions painted with ink.

Furthermore, the opening portion is not limited to the ventilation openings 41. For example, the card insertion opening 37, the medium insertion opening 38 and the plurality of connectors provided in the recess portion 42 may be an example of the opening portions. For example, the printed wiring board 24 is visible from the card insertion opening 37, the second region 53 is located at a position visible from the card insertion opening 37.

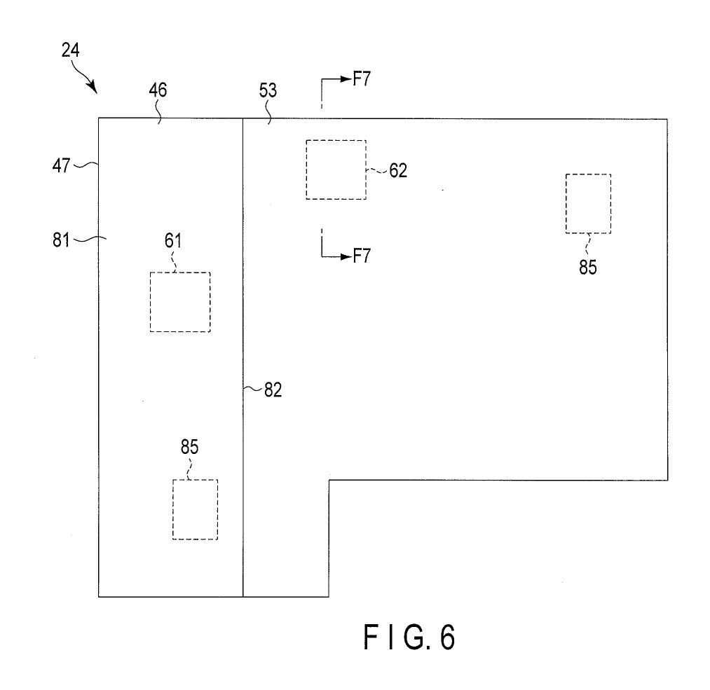

Next, the second embodiment will now be described with reference to FIGS. 6 to 8. Note that in the embodiments which will now be described below, the structural parts having the same functions as those of the television 1 of the first embodiment will be designated by the same reference numerals. Further, with regard to the structural parts, the entire or part of the explanation thereof will be omitted in some cases.

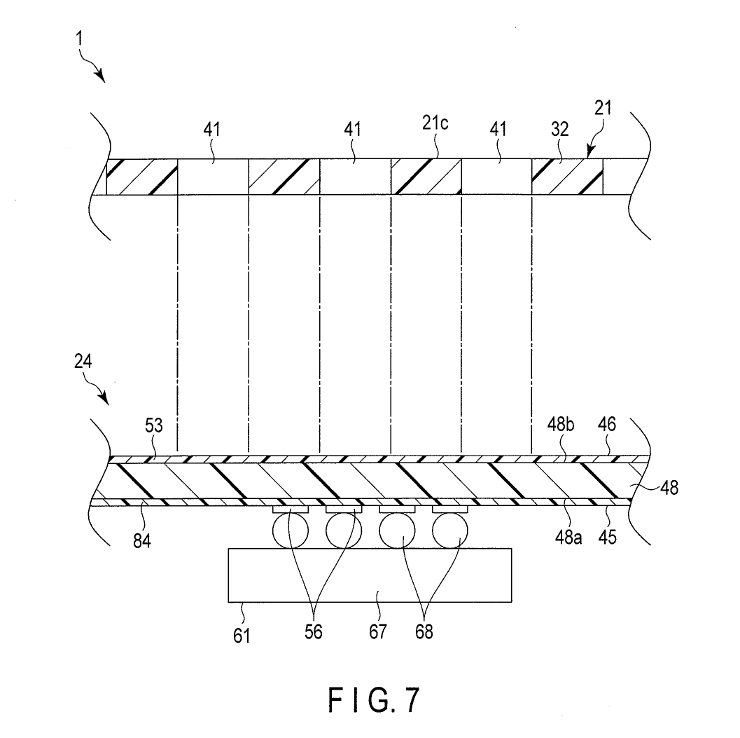

FIG. 6 is an exemplary plan view showing the printed circuit board 24 of the second embodiment, and FIG. 7 is an exemplary cross sectional view of a part of the printed circuit board 24, taken along the line F7-F7 of FIG. 6. In the second embodiment, the first surface 45 faces the display module 22, whereas the second surface 46 faces the inner surface of the rear cover 32.

As shown in FIG. 6, the second region 53 and a third region 81 are formed in the second surface 46. The second region 53 is formed of a solder resist colored in delustered black. The delustered black is an example of the second color. The delustered black, which is an example of the second color, has a resolution lower than that of blue, which is an example of the first color. The delustered black can make fine scratches inconspicuous more than glossy color.

The second region 53 is set adjacent to the third region 81. Between the second region 53 and the third region 81, a linear boundary 82 is drawn to partition them from each other. As shown in FIG. 7, a part of the second region 53 is placed in the vicinity of the plurality of ventilation openings 41. In other words, the part of the second region 53 is placed at a position visible from the plurality of ventilation openings 41. The second region 53 is colored in black, which is a dark cooler, and therefore it is not conspicuous when viewed through the ventilation openings 41.

The third region 81 is formed of a solder resist colored in glossy black. Glossy black is an example of the third color which is different from the first color or second color. A part of the third region 81 is placed at a position visible through the card insertion opening 37.

As shown in FIG. 7, a first region 84 is formed in the entirety of the first surface 45 of the printed wiring board 24. The first region 84 is formed of a solder resist colored in blue which is an example of the first color. As indicated by broken lines in FIG. 6, the so-called high density (fine line) mounting parts, two BGAs 61 and 62 and two QFPs 85 are mounted in the first region 84.

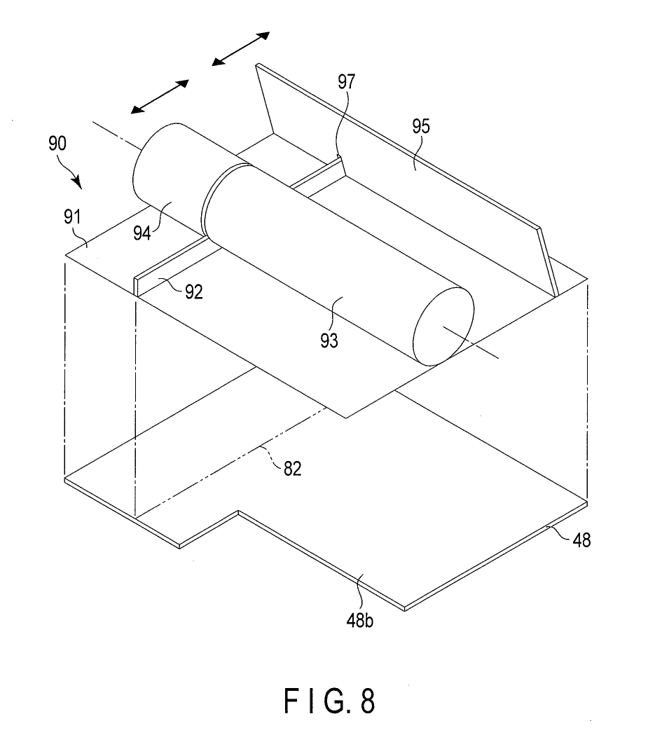

FIG. 8 is an exemplary perspective view schematically showing a copper clad laminate 48 before the solder resist is applied and a coating device 90 which applies the solder resist on the copper clad laminate 48. In FIG. 8, the location where the boundary 82 between the second region 53 and the third region 81 is indicated by an alternate long and two short dashes line.

As shown in FIG. 8, the coating device 90 applies the solder resist on the other surface 48b of the copper clad laminate 48. The coating device 90 comprises a screen 91, a partition 92, a pair of rolls 93 and 94 and a squeegee 95.

The screen 91 is formed of a mesh-like sheet held on the outer frame. The screen 91 is set to face the other surface 48b of the copper clad laminate 48.

The partition 92 is mounted on, for example, the outer frame of the screen 91. The partition 92 is placed on the position where the boundary 82 between the second region 53 and the third region 81 is provided (that is, the position to cover the boundary 82).

A pair of rolls 93 and 94 are arranged in line on the same axis. The pair of rolls 93 and 94 sandwich the partition 92 therebetween. The pair of rolls 93 and 94 moves along the partition 92 by a roll drive device. The roll 93 moves on the portion where the second region 53 is formed, whereas the other roll 94 moves on the portion where the third region 81 is formed. The pair of rolls 93 and 94 can be moved in the direction approaching the copper clad laminate 48 by the roll drive device.

The roll 93 is connected to a storage portion which stores the solder resist colored in the delustered black. This solder resist enters a plurality of grooves formed in the roll 93. The other roll 94 is connected to a storage portion which stores the solder resist colored in the glossy black. This solder resist enters a plurality of grooves formed in the roll 94. With the partition 92, it is possible to prevent the solder resist of the roll 93 and the solder resist of the other roll 94 from being mixed together.

The squeegee 95 is formed into a rectangular plate shape which has a notch 97 to hold the partition 92. The squeegee 95 moves along the partition 92 by a squeegee drive device. Further, the squeegee 95 can be moved in the direction approaching the copper clad laminate 48 by the squeegee drive device.

In the second embodiment, the second and third regions 53 and 81 are formed, for example, in the following manner. First, the screen 91 is set to face the other surface 48b of the copper clad laminate 48. Next, the pair of rolls 93 and 94 are moved while being in contact with the screen 91. Thus, both of the solder resist colored in delustered black and the solder resist colored in glossy black penetrate into the screen 91. Through the mesh of the screen 91, both of the solder resist colored in delustered black and the solder resist colored in glossy black attach to the other surface 48b of the copper clad laminate 48.

Next, the squeegee 95 is moved while being in contact with the screen 91. Thus, both of the solder resist colored in delustered black and the solder resist colored in glossy black applied onto the copper clad laminate 48 are formed into a surface. In other words, the solder resist colored in delustered black and the solder resist colored in glossy black are formed to have a uniform thickness.

Next, the coating device 90 is removed from the copper clad laminate 48, and the coated solder resist is subjected to masking. Then, the solder resist is exposed to light, and then subjected to etching, thereby forming the second region 53 and the third region 81 as shown in FIG. 6.

According to the television 1 having the above-described structure, the second region 53, a part of which is located at a position visible from the ventilation openings 41, is colored in delustered black. With this structure, the printed wiring board 24 is made inconspicuous, and thus the design of the television 1 is improved.

On the other hand, the first region 84 colored in blue is formed in the entirety of the first surface 45. With this structure, in the first region 84, the pads 56 fine to match the BGAs 61 and 62, and pads fine to match the QFP 85 can be formed. Further, since the BGAs 61 and 62 and the QFP 85 are mounted on the first region 84, which makes it possible to facilitate to perform the optical automatic inspection.

As described above, the color of the first region 84 and the color of the second region 53 can be determined in accordance with the conditions of the first region 84 and the second region 53, respectively. In this manner, even if the section visible from the ventilation openings 41 is colored in black, the high density (fine line) mounting parts, namely, the BGAs 61 and 62 and the QFP 85 can be easily mounted on the printed wiring board 24. Thus, the design of the television 1 can be improved by suppressing the demerits.

The second region 53 is colored in delustered black, whereas the third region 81 is colored in glassy black. That is, the second surface 46 of the printed circuit board 24 is colored in black. The second surface 46, unlike the first surface 45, does not need an electronic part such as BGA 16 mounted thereon, or the optical automatic inspection carried out therefore. Thus, the demerit created by coloring the second surface 46 in black can be suppressed.

The second region 53, a part of which is located at a position visible from the ventilation openings 41, is colored in delustered black. On the other hand, the third region 81, a part of which is located at a position visible from the card insertion opening 37, is colored in glossy black. Thus, the color is changed from one place visible from the openings to another and thus the design of the television 1 can be improved.

With the pair of rolls 93 and 94, the solder resist colored in delustered black and the solder resist colored in glossy black are applied onto the copper clad laminate 48. In this manner, the second region 53 and the third region 81 can be formed at the same time.

The two embodiments described above are described in connection with the case where glossy or delustered black is an example of the second color, but the second color is not limited to this. The second color may be arbitrary as long as it is different from the first color, such as white or red. Further, the second color is not limited to an inconspicuous color. For example, by employing a conspicuous bright color as the second color, the design of the television can be improved.

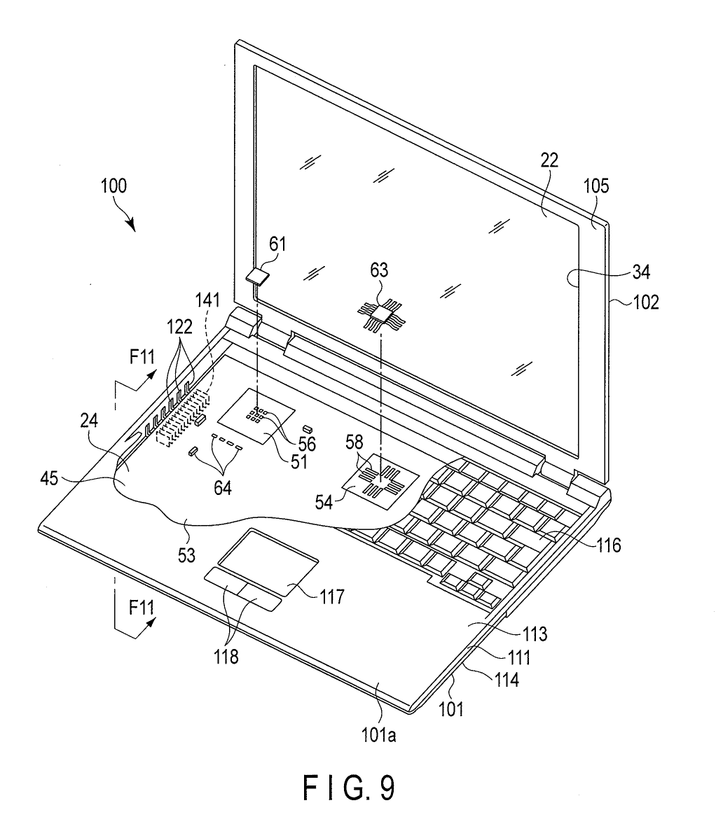

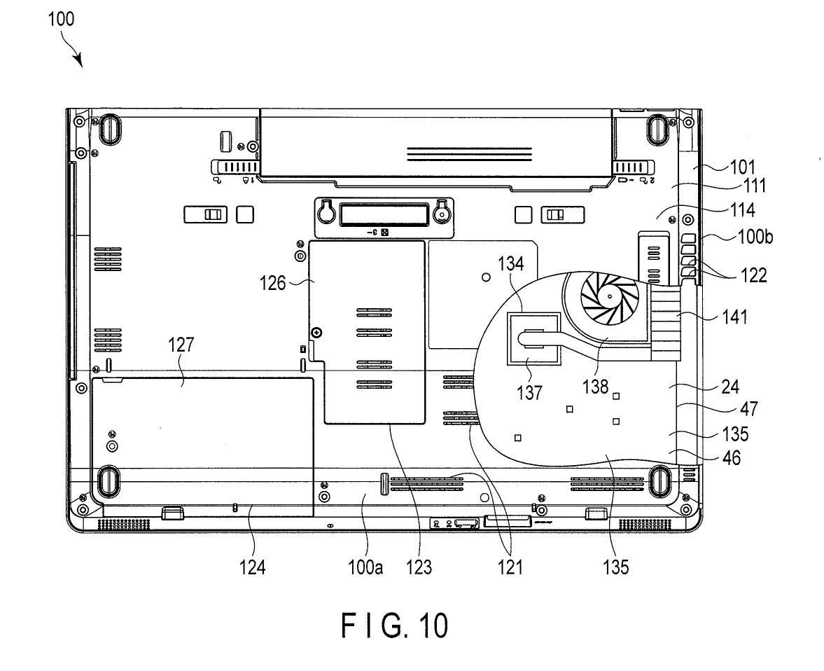

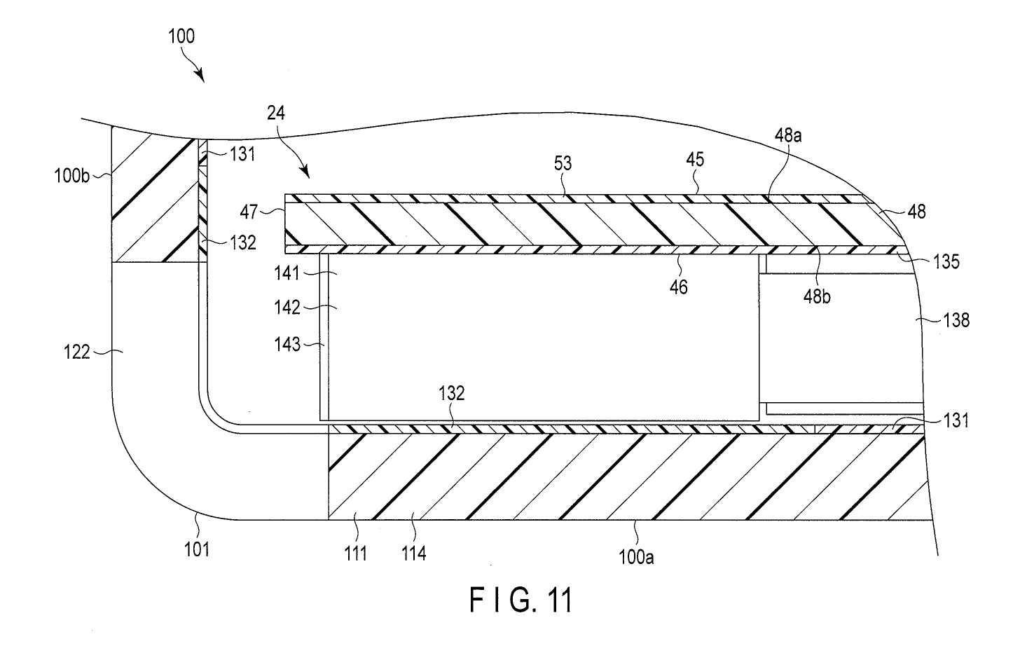

Next, the third embodiment will now be described with reference to FIGS. 9 to 11. FIG. 9 is an exemplary perspective and partially cut-away view of a portable computer 100. FIG. 10 is an exemplary plan and partially cut-away view showing a bottom surface 100a of the portable computer 100. FIG. 11 is an exemplary cross sectional view of a part of the portable computer 100, taken along the line F11-F11 of FIG. 9.

As shown in FIG. 9, the portable computer 100 comprises a main unit 101 and a display unit 102. The main unit 101 and the display unit 102 are coupled together by a hinge.

The display unit 102 comprises a display housing 105 and a display module 22. The display module 22 is contained in the display housing 105. A display opening 34 is formed in the display housing 105 to expose the display module 22.

The main unit 101 comprises a housing 111 and a printed wiring board 24. The printed wiring board 24 in the third embodiment is a printed circuit board of the so-called double sided mounting mode. The printed wiring board 24 is contained in the housing 111. The housing 111 comprises a top cover 113 and a bottom cover 114.

The top cover 113 forms an upper surface (surface on the display unit 102 side) 101a of the main unit 101. On the upper surface 101a, provided are a keyboard 116, a touch pad 117 and a pair of buttons 118.

As shown in FIG. 10, the bottom cover 114 forms the bottom surface (surface opposite to the display unit 102) 100a, and side surfaces 100b of the portable computer 100. It should be noted that the side surfaces 100b may be formed as parts of the top cover 113.

In the bottom surface 100a of the portable computer 100, formed are a plurality of air inlets 121, a plurality of air exhaust outlets 122, a memory container portion 123 and a storage container portion 124. The air inlets 121 and the air exhaust outlets 122 are examples of ventilation openings and opening portions, respectively. The memory container portion 123 and the storage container portion 124 are examples of the opening portions. The plurality of air exhaust outlets 122 are formed from the bottom surface 100a over to the side surfaces 100b.

The memory container portion 123 is covered by a first cover 126, which is fixed to the bottom surface 100a with a screw. A memory is contained in the memory container portion 123. A part of the printed wiring board 24 is visible from this memory container portion 123.

The storage container portion 124 is covered by a second cover 127, which is fixed to the bottom surface 100a with a screw. A storage such as HDD is contained in the storage container portion 124. A part of the printed wiring board 24 is visible from this storage container portion 124.

As shown in FIG. 11, the inner surface of the bottom cover 114 comprises a first portion 131 and a plurality of second portions 132. The plurality of second portions 132 are formed around the air inlets 121, air exhaust outlets 122, memory container portion 123 and storage container portion 124, respectively, which are examples of the opening portions. The plurality of second portions 132 are visible from each of the air inlets 121, air exhaust outlets 122, memory container portion 123 and storage container portion 124. The first portion 131 is formed to surround the plurality of second portions 132.

The first portion 131 is a portion colored in gray with ink. Note that the color of the first portion 131 may be some other color such as blue, or the same as the color of the material of the bottom cover 114.

The second portions 132 is portions colored in black with ink. This black color is darker than the color of the first portion 131, and is blackish. Note that the second portions 132 may be painted in some other color such as red.

As shown in FIG. 9, the first surface 45 of the printed wiring board 24 faces the inner surface of the top cover 113. In the first surface 45, formed are the first region 51, the second region 53 and the third region 54. On the first surface 45, mounted are a BGA 61, a QFP 63 and a plurality of other electronic parts 64.

As shown in FIG. 10, the second surface 46 of the printed wiring board 24 faces the inner surface of the bottom cover 114. The second surface 46 of the third embodiment is an example of the mounting surface as in the case of the first surface 45. In the second surface 46, formed are the first region 134 and the second region 135.

The first region 134 is formed of a solder resist colored in blue, which is an example of the first color. The first region 134 comprises a plurality of pads, which are an example of the conducting portions. On the first region 134, a CPU 137 is mounted, which is an example of the electronic part.

The second region 135 is formed of a solder resist colored in black, which is an example of the second color. The second region 135 is visible from each of the air inlets 121, air exhaust outlets 122, memory container portion 123 and storage container portion 124. The second region 135 is formed to surround the first region 134.

A cooling device 138 is mounted on the second surface 46. The cooling device 138 comprises a copper-made fin 141. The fin 141 is an example of the module. The fin 141 is located in the vicinity of the air exhaust outlets 122. The fin 141 is connected indirectly to the CPU 137 so as to release the heat generated from the CPU 137.

As shown in FIG. 11, the fin 141 comprises a first region 142 and a second region 143. The second region 143 is an end portion of the fin 141 which faces the air exhaust outlets 122, and is exposed from the air exhaust outlets 122. The second region 143 is colored in black, which is an example of the second color, with ink.

The area of the first region 142 is larger than that of the second region 143. The first region 142 is not painted, and the material part of the fin 141 is exposed. That is, the color of the first region 142 is that of copper, which is the material for the fin 141. The color of copper is an example of the first color.

According to the portable computer 100 having the above-described structure, the second region 143, which is located at a position visible from the air exhaust outlets 122, is colored in black. With this structure, the fin 141 is made inconspicuous, and thus the design of the portable computer 100 is improved.

On the other hand, the color of the first region 142 is that of copper, which is the material for the fin 141. That is, the first region 142, in which the portion of the material of the fin 141 is exposed, has a thermal conductivity higher than that of the second region 143, which is painted.

As described above, the color of the first region 142 and the color of the second region 143 can be determined in accordance with the conditions of the first region 142 and the second region 143, respectively. In this manner, even if the section visible from the air exhaust outlets 122 is colored in black, the release of the heat from the CPU 137 can be effectively carried out. Thus, the design of the portable computer 100 can be improved by suppressing the demerits.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television comprising:
a housing comprising a front surface, a display opening in the front surface, a rear surface, and a ventilation opening in the rear surface;
a display in the housing, the display exposed through the display opening and configured to display an image;
a tuner in the housing;
a substrate in the housing, the substrate comprising a mounting surface; and
an electronic part comprising a terminal, the electronic part mounted on the mounting surface of the substrate;
wherein the mounting surface comprises a first region comprising a conducting portion configured to be electrically connected to the terminal of the electronic part, the first region colored in a first color, and a second region, a part of the second region placed at a position visible through the ventilation opening, the second region colored in a second color of a resolution lower than a resolution of the first color, the second region placed adjacent to the first region.

2. An electronic apparatus comprising:
a housing comprising an opening;
a substrate in the housing, the substrate comprising a first region comprising a conducting portion, the first region colored in a first color, and a second region configured to be visible through the opening, the second region colored in a second color different from the first color; and
an electronic part configured to be electrically connected to the conducting portion.

3. The electronic apparatus of claim 2, wherein the first region is formed of a solder resist colored in the first color, and the second region is formed of a solder resist colored in the second color.

4. The electronic apparatus of claim 3, wherein the first color has a resolution higher than a resolution of the second color.

5. The electronic apparatus of claim 3, wherein
the substrate comprises a first surface and a second surface on an opposite side to the first surface, and
the first region and the second region are formed in the first surface of the substrate.

6. The electronic apparatus of claim 4, wherein
the substrate comprises a first surface and a second surface on an opposite side to the first surface, and
the first region and the second region are formed in the first surface of the substrate.

7. The electronic apparatus of claim 5, wherein
the electronic part comprises a package portion and a terminal projecting from the package portion, the electronic part connected to the conducting portion, and
the first region is covered by the package portion.

8. The electronic apparatus of claim 6, wherein
the electronic part comprises a package portion and a terminal projecting from the package portion, the electronic part connected to the conducting portion, and
the first region is covered by the package portion.

9. The electronic apparatus of claim 3, wherein
the substrate comprises a first surface and a second surface on an opposite side to the first surface,
the first region is formed in the first surface of the substrate, and
the second region is formed in the second surface of the substrate.

10. The electronic apparatus of claim 4, wherein
the substrate comprises a first surface and a second surface on an opposite side to the first surface,
the first region is formed in the first surface of the substrate, and
the second region is formed in the second surface of the substrate.

11. The electronic apparatus of claim 2, wherein
the substrate comprises a third region colored in a third color different from the first color or the second color.

12. The electronic apparatus of claim 2, wherein
the substrate comprises a first surface, a second surface on an opposite side to the first surface, and an edge portion formed from the first surface over to the second surface and colored in the second color.

13. An electronic apparatus comprising:
a housing comprising an opening; and
a module comprising a first region colored in a first color and a second region exposed through the opening, the second region colored in a second color different from the first color.
